(19) United States
(12) Patent Application Publication
(10) Pub. No.: US 2024/0224803 A1
(43) Pub. Date: Jul. 4, 2024

(54) APPARATUS

(71) Applicant: LG Display Co., Ltd., Seoul (KR)

(72) Inventors: DoHyeong KIM, Paju-si (KR); MinKyu CHOI, Paju-si (KR); Seungo JEON, Paju-si (KR); Daeho KIM, Paju-si (KR); Inchan JEONG, Paju-si (KR); HyeonSeok KIM, Paju-si (KR)

(73) Assignee: LG Display Co., Ltd., Seoul (KR)

(21) Appl. No.: 18/540,038

(22) Filed: Dec. 14, 2023

(30) Foreign Application Priority Data
Dec. 29, 2022 (KR) 10-2022-0188189

(51) Int. Cl. H10N 30/20; H04R 17/00; H10N 30/80; H10N 30/87; H10N 30/88; H10N 39/00

(52) U.S. Cl. CPC H10N 30/2027; H04R 17/00; H10N 30/802; H10N 30/875; H10N 30/883; H10N 39/00; H04R 2217/01

(57) ABSTRACT

An apparatus may include a vibration member having a plane portion and a round portion extended to be rounded from the plane portion, and a vibration device connected to the vibration member. The apparatus may improve sound characteristics and/or sound pressure characteristics. Further, the apparatus may output sound in various directions.

### CROSS-REFERENCE TO RELATED APPLICATIONS

This application claims the benefit of the Korean Patent Application No. 10-2022-0188189 filed on Dec. 29, 2022, which is hereby incorporated by reference as if fully set forth herein.

### BACKGROUND

### Technical Field

The present disclosure relates to an apparatus, and more particularly, to an apparatus capable of outputting sound.

### Discussion of the Related Art

An apparatus includes a separate speaker or sound apparatus to provide sound. The sound apparatus has a vibration meter that converts an input electrical signal into physical vibration. A piezoelectric speaker made of a piezoelectric element has advantages of being lightweight and low power consumption, and thus is used for various purposes.

Since the sound generated by the sound apparatus is output in a direction of a backside or a side of the apparatus not a front side of the apparatus, the sound does not move toward a user, thereby disturbing a viewer's immersion. Accordingly, a piezoelectric speaker that enables listening in various directions has been developed.

### SUMMARY

Accordingly, embodiments of the present disclosure are directed to an apparatus that substantially obviates one or more of the problems due to limitations and disadvantages of the related art.

An aspect of the present disclosure is to provide an apparatus capable of improving sound characteristics and/or sound pressure characteristics and outputting sound in various directions.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, an apparatus comprises a vibration member including a plane portion and a round portion extended to be rounded from the plane portion, and a vibration device connected to the vibration member.

According to one embodiment of the present disclosure, the apparatus may improve sound characteristics and/or sound pressure characteristics and output sound in various directions.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a perspective view illustrating an apparatus according to the embodiment of the present disclosure;

FIG. 2 is a cross-sectional view taken along line I-I′ shown in FIG. 1;

FIG. 3 is another cross-sectional view taken along line I-I′ shown in FIG. 1;

FIG. 4 is a view illustrating a vibration device according to the embodiment of the present disclosure;

FIG. 5 is a cross-sectional view taken along line II-II′ shown in FIG. 4;

FIG. 6 is a cross-sectional view taken along line III-III′ shown in FIG. 4;

FIG. 7 is a plan view illustrating a frequency measurement range of an apparatus according to the embodiment of the present disclosure; and

FIG. 8 is a view illustrating sound output characteristics per frequency of an apparatus according to the embodiment of the present disclosure.

### DETAILED DESCRIPTION

Reference is now be made in detail to embodiments of the present disclosure, examples of which may be illustrated in the accompanying drawings. In the following description, when a detailed description of well-known functions or configurations may unnecessarily obscure aspects of the present disclosure, the detailed description thereof may be omitted for brevity. The progression of processing steps and/or operations described is an example; however, the sequence of steps and/or operations is not limited to that set forth herein and may be changed, with the exception of steps and/or operations necessarily occurring in a particular order.

Unless stated otherwise, like reference numerals may refer to like elements throughout even when they are shown in different drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Furthermore, the present disclosure is only defined by scopes of claims.

The shapes, sizes, areas, ratios, angles, numbers, and the like disclosed in the drawings for describing embodiments of the present disclosure are merely examples, and thus, the present disclosure is not limited to the illustrated details.

When the term “comprise,” “have,” “include,” “contain,” “constitute,” “make up of,” “formed of,” or the like is used, one or more other elements may be added unless a term such as “only” or the like is used. The terms used in the present disclosure are merely used in order to describe particular embodiments, and are not intended to limit the scope of the present disclosure. The terms used herein are merely used in order to describe example embodiments, and are not intended to limit the scope of the present disclosure. The terms of a singular form may include plural forms unless the context clearly indicates otherwise. The word “exemplary” is used to mean serving as an example or illustration. Embodiments are example embodiments. Aspects are example aspects. Any implementation described herein as an “example” is not necessarily to be construed as preferred or advantageous over other implementations.

In one or more aspects, an element, feature, or corresponding information (e.g., a level, range, dimension, size, or the like) is construed as including an error or tolerance range even where no explicit description of such an error or tolerance range is provided. An error or tolerance range may be caused by various factors (e.g., process factors, internal or external impact, noise, or the like). Further, the term “may” encompasses all the meanings of the term “can.”

In describing a positional relationship, where the positional relationship between two parts is described, for example, using “on,” “over,” “under,” “above,” “below,” “beneath,” “near,” “close to,” “adjacent to,” “beside,” “next to,” or the like, one or more other parts may be located between the two parts unless a more limiting term, such as “immediate(ly),” “direct(ly),” or “close(ly),” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

In describing a temporal relationship, when the temporal order is described as, for example, “after,” “subsequent,” “next,” “before,” “preceding,” “prior to,” or the like, a case that is not consecutive or not sequential may be included unless a more limiting term, such as “just,” “immediate(ly),” or “direct(ly),” is used.

It is understood that, although the term “first,” “second,” or the like may be used herein to describe various elements, these elements should not be limited by these terms. These terms are only used to distinguish one element from another. For example, a first element could be a second element, and, similarly, a second element could be a first element, without departing from the scope of the present disclosure. Furthermore, the first element, the second element, and the like may be arbitrarily named according to the convenience of those skilled in the art without departing from the scope of the present disclosure. The terms “first,” “second,” and the like may be used to distinguish components from each other, but the functions or structures of the components are not limited by ordinal numbers or component names in front of the components.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of elements.

For the expression that an element or layer is “connected,” “coupled,” or “adhered” to another element or layer the element or layer can not only be directly connected, coupled, or adhered to another element or layer, but also be indirectly connected, coupled, or adhered to another element or layer with one or more intervening elements or layers disposed or interposed between the elements or layers, unless otherwise specified.

For the expression that an element or layer “contacts,” “overlaps,” or the like with another element or layer, the element or layer can not only directly contact, overlap, or the like with another element or layer, but also indirectly contact, overlap, or the like with another element or layer with one or more intervening elements or layers disposed or interposed between the elements or layers, unless otherwise specified.

The term “at least one” should be understood as including any and all combinations of one or more of the associated listed items. For example, the meaning of “at least one of a first item, a second item, and a third item” denotes the combination of items proposed from two or more of the first item, the second item, and the third item as well as only one of the first item, the second item, and the third item.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C. Furthermore, an expression “element A/element B” may be understood as element A and/or element B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

Features of various embodiments of the present disclosure may be partially or overall coupled to or combined with each other, and may be variously inter-operated, linked or driven together. The embodiments of the present disclosure may be carried out independently from each other or may be carried out together in co-dependent or related relationship. In one or more aspects, the components of each apparatus according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

Hereinafter, embodiments of a display apparatus according to various example embodiments of the present disclosure will be described in detail with reference to the accompanying drawings. With respect to reference numerals to elements of each of the drawings, although the same elements may be illustrated in other drawings, like reference numerals may refer to like elements unless stated otherwise. In addition, for convenience of description, a scale, dimension, size, and thickness of each of the elements illustrated in the accompanying drawings may differ from an actual scale, dimension, size, and thickness, and thus, embodiments of the present disclosure are not limited to a scale, dimension, size, and thickness illustrated in the drawings.

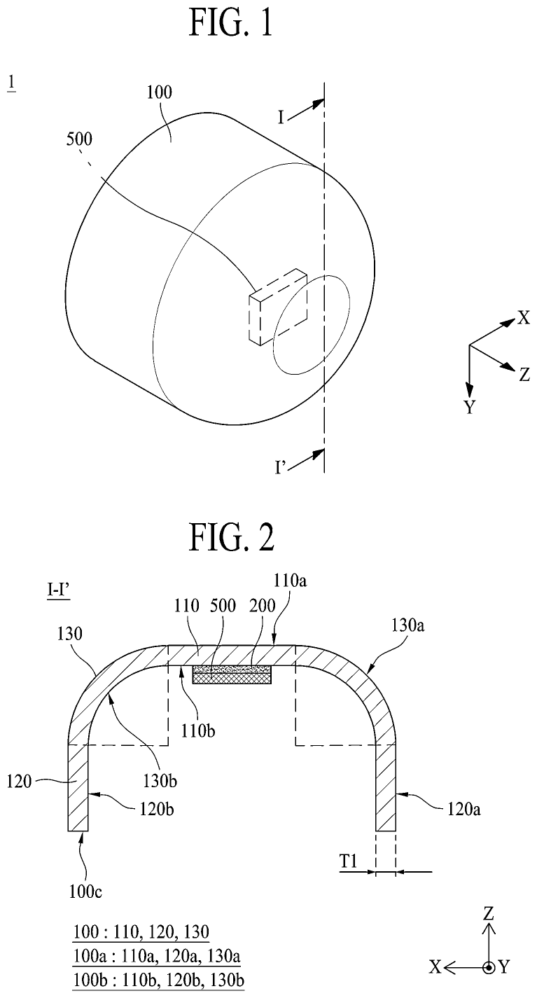

FIG. 1 is a perspective view illustrating an apparatus according to the embodiment of the present disclosure. FIG. 2 is a cross-sectional view taken along line I-I′ shown in FIG. 1.

Referring to FIGS. 1 and 2, an apparatus 1 according to the embodiment of the present disclosure may implement or realize a sound apparatus, a sound output apparatus, a vibration apparatus, a vibration generating apparatus, a sound bar, a sound system, a sound apparatus for an electronic apparatus, a sound apparatus for a display apparatus, a sound apparatus for a transportation apparatus or a sound bar for a transportation apparatus. For example, the transportation apparatus may include one or more seats and one or more windows. For example, the transportation apparatus may include a vehicle, a train, a ship or an aircraft, and the embodiments of the present disclosure are not limited thereto. In addition, the apparatus 1 according to the embodiment of the present disclosure may implement or realize an analog signage or a digital signage, such as an advertisement signboard, a poster and a guide plate.

The apparatus 1 according to one embodiment of the present disclosure may be coupled to a display apparatus that includes a plurality of pixels, but the embodiments of the present disclosure are not limited thereto. The display apparatus may include a display panel including a plurality of pixels constituting a black-and-white or color image, and a driver for driving the display panel. The pixel may be a subpixel implementing one of a plurality of colors constituting a color image.

The apparatus 1 according to the embodiment of the present disclosure may be included in a set electronic apparatus or a set device (or set apparatus) such as a laptop computer, a television, a computer monitor, an automotive apparatus for a vehicle, an equipment apparatus including another type of a vehicle, or a mobile electronic apparatus such as a smart phone or an electronic pad, which is a complete product or a final product that includes a display panel such as a liquid crystal display panel or an organic light emitting display panel.

The apparatus 1 according to the embodiment of the present disclosure may include a vibration member 100 and one or more vibration devices 500.

The vibration member 100 may generate vibration or output sound (or sound waves) in accordance with displacement (or driving) of the one or more vibration devices 500. The vibration member 100 may be a vibration target, a display member, a display panel, a signage panel, a passive vibration plate, a front member, a rear member, a vibration panel, a sound panel, a passive vibration panel, a sound output plate, a sound vibration plate or an image screen, but the embodiments of the present disclosure are not limited thereto.

The vibration member 100 according to one embodiment of the present disclosure may include a polygonal shape that includes a rectangular shape or a square shape, but the embodiments of the present disclosure are not limited thereto. The vibration member 100 may include a horizontal length parallel with a first direction X, and a vertical length parallel with a second direction Y. For example, based on the same plane, the first direction X may be a first horizontal direction or a first horizontal length direction of the vibration member 100, and the second direction Y may be a second horizontal direction orthogonal to the first direction X or a second horizontal length direction of the vibration member 100.

The vibration member 100 according to one embodiment of the present disclosure may include a structure having the same thickness as a whole, but the embodiments of the present disclosure are not limited thereto. For example, the vibration member 100 may include a planar structure and a non-planar structure, which have the same thickness as a whole, but the embodiments of the present disclosure are not limited thereto. For example, a thickness Tl of the vibration member 100 may be in the range of 1 mm to 3 mm.

According to the embodiment of the present disclosure, the vibration member 100 may include a plane portion 110, a side portion 120, and a round portion 130.

According to the embodiment of the present disclosure, each of the plane portion 110, the side portion 120 and the round portion 130 may include a first surface 110a, 120a and 130a and a second surface 110b, 120b and 130b. In the vibration member 100, the first surface 110a, 120a and 130a may be outer sides. The second surface 110b, 120b and 130b may be inner sides. According to the embodiment of the present disclosure, each of the plane portion 110, the side portion 120 and the round portion 130 may have the same thickness as a whole, but the embodiments of the present disclosure are not limited thereto.

According to the embodiment of the present disclosure, the plane portion 110 may include a flat panel structure having a uniform thickness as a whole. For example, the plane portion 110 may include a circular flat panel structure. For example, the plane portion 110 may include a first surface 110a and a second surface 110b. In the plane portion 110, the first surface 110a may be an outer side. In the plane portion 110, the second surface 110b may be an inner side. The vibration device 500 may be disposed on the plane portion 110. The vibration device 500 may be disposed on an inner side of the plane portion 110. For example, the vibration device 500 may be connected to the second surface 110b of the plane portion 110. For example, the thickness of the plane portion 110 may be in the range of 1 mm to 3 mm.

According to the embodiment of the present disclosure, the side portion (or a second extension portion) 120 may be configured to be perpendicular to the plane portion 110. The side portion 120 may be connected to the plane portion 110 by using the round portion 130. The side portion 120 may include a flat panel structure having a uniform thickness as a whole. For example, the side portion 120 may include a cylindrical structure that is hollow. For example, a circumference of the side portion 120 may be greater than that of the plane portion 110. For example, a diameter of the side portion 120 may be greater than that of the plane portion 110. Therefore, the round portion 130 may be extended to be rounded from the plane portion 110 toward the side portion 120. For example, the side portion 120 may include a first surface 120a and a second surface 120b. In the side portion 120, the first surface 120a may be an outer side. In the side portion 120, the second surface 110b may be an inner side. For example, the thickness of the side portion 120 may be in the range of 1 mm to 3 mm.

According to the embodiment of the present disclosure, the round portion (or a first extension portion) 130 may include a non-flat panel structure (or a non-planar structure) having a uniform thickness as a whole. The round portion 130 may be extended to be rounded in a direction from the plane portion 110 toward the side portion 120. For example, the round portion 130 may be extended to be rounded from an end of the plane portion 110 to an end of the side portion 120. The round portion 130 may be extended to be rounded in a direction perpendicular to the plane portion 110 from the plane portion 110. The round portion 130 may connect the plane portion 110 with the side portion 120. For example, the thickness of the round portion 130 may be in the range of 1 mm to 3 mm. For example, a curvature radius R of the round portion 130 may be 25 mm to 100 mm.

The vibration member 100 may have an internal space by the second surface 110b of the plane portion 110, the second surface 120b of the side portion 120 and the second surface 130b of the round portion 130. Since the second surface 110b of the plane portion 110, the second surface 120b of the side portion 120 and the second surface 130b of the round portion 130 are connected to one another, the vibration member 100 may have the internal space. The internal space may be configured by an inner side of each of the plane portion 110, the round portion 130 and the side portion 120. The internal space may include a shape in which one side (or upper side) is open. For example, the internal space may be an accommodation space, a storage space, a gap space, an air space, a vibration space, a sound space, a sound box or a sealed space, but the embodiments of the present disclosure are not limited thereto. According to the embodiment of the present disclosure, the vibration device 500 may be disposed in the internal space.

The vibration member 100 according to one embodiment of the present disclosure may be configured to be opaque. For example, the vibration member 100 may include a porous plastic material or an ultra-fine foam plastic material, which has material properties suitable for outputting sound in accordance with vibration. For example, the vibration member 100 may include an acrylonitrile butadiene styrene copolymer (ABS) resin. For example, the vibration member 100 may be easily manufactured by a method such as injection and molding, and the embodiments of the present disclosure are not limited thereto.

The vibration member 100 according to one embodiment of the present disclosure may implement or realize an analog signage or a digital signage such as an advertisement signboard, a poster and a guide plate. For example, when the vibration member 100 realizes a signage panel, the analog signage may include signage contents such as a sentence, a picture and a symbol. The signage contents may be disposed to be visible in the vibration member 100. For example, the signage contents may be attached to a third surface 100c connecting a first surface 100a with a second surface 100b of the vibration member 100. For example, the signage content may be directly attached to the third surface 100c connecting the first surface 100a with the second surface 100b of the vibration member 100.

The one or more vibration devices 500 may be configured to vibrate the vibration member 100. The one or more vibration devices 500 may be disposed or configured in the vibration member 100. The one or more vibration devices 500 may be configured to be vibrated (or displaced or driven) in accordance with an applied driving signal (or an electrical signal or a voice signal) to vibrate (or displace) the vibration member 100. For example, the one or more vibration devices 500 may be active vibration members, vibration generators, vibration structures, vibrators, vibration generating elements, sound generators, sound elements, sound generating structures or sound generating elements, and the embodiments of the present disclosure are not limited thereto.

The one or more vibration devices 500 according to the embodiment of the present disclosure may include a piezoelectric material or an electroactive material, which has piezoelectric characteristics. The one or more vibration devices 500 may be autonomously vibrated (or displaced) or may vibrate (or displace) the vibration member in accordance with vibration (or displacement) of the piezoelectric material based on the driving signal applied to the piezoelectric material. The one or more vibration devices 500 may be vibrated (or displaced or driven) as contraction and/or expansion is alternately repeated by a piezoelectric effect (or piezoelectric characteristics). For example, the one or more vibration devices 500 may be vibrated (or displaced or driven) in a vertical direction (or thickness direction) Z as contraction and/or expansion is alternately repeated by a reverse piezoelectric effect.

The one or more vibration devices 500 according to one embodiment of the present disclosure may include a rectangular shape having a first length parallel with the first direction X and a second length parallel with the second direction Y. For example, the one or more vibration devices 500 may include a square shape in which a first length and a second length are the same as each other, but the embodiments of the present disclosure are not limited thereto.

The one or more vibration devices 500 according to one embodiment of the present disclosure may be connected or coupled to the vibration member 100 by means of a connection member 200. For example, the one or more vibration devices 500 may be connected to or supported on the second surface 100b of the vibration member 100 by the connection member 200, and the embodiments of the present disclosure are not limited thereto. For example, the one or more vibration devices 500 may be connected to or supported on the second surface 110b of the plane portion 110 by the connection member 200, and the embodiments of the present disclosure are not limited thereto. For example, the connection member 200 may be an adhesive member, and the embodiments of the present disclosure are not limited thereto.

The connection member 200 may be disposed between the vibration device 500 and the vibration member 100, and may connect or couple the vibration device 500 to the vibration member 100. For example, the vibration device 500 may be connected or coupled to the second surface 100b of the vibration member 100 by means of the connection member 200 so that the vibration device 500 may be supported or disposed on the second surface 100b of the vibration member 100. For example, the vibration device 500 may be connected or coupled to the second surface 110b of the plane portion 110 by means of the connection member 200 so that the vibration device 500 may be supported or disposed on the second surface 110b of the plane portion 110.

The connection member 200 according to the embodiment of the present disclosure may include an adhesive layer (or viscosity layer) having excellent tight coupling (or adhesion). For example, the connection member 200 may be made of a material that includes an adhesive layer having excellent tight coupling or adhesion to each of the second surface 100b of the vibration member 100 and the vibration device 500. For example, the connection member 200 may include a foam pad, a double-sided tape, a double-sided foam pad, a double-sided foam tape, an adhesive, a double-sided adhesive tape, a double-sided adhesive foam pad or a viscosity sheet, and the embodiments of the present disclosure are not limited thereto. For example, when the connection member 200 includes a viscosity sheet (or viscosity layer), the connection member 200 may include only an adhesive layer or a viscosity layer without a base member such as a plastic material.

The adhesive layer (or viscosity layer) of the connection member 200 according to the embodiment of the present disclosure may include epoxy, acrylic, silicone or urethane, and the embodiments of the present disclosure are not limited thereto. The adhesive layer (or viscosity layer) of the connection member 200 according to another embodiment of the present disclosure may include a pressure sensitive adhesive (PSA), an optically clear adhesive (OCA) or an optically clear resin (OCR), and the embodiments of the present disclosure are not limited thereto. For example, the adhesive layer of the connection member 200 may include an acryl-based material having relatively excellent adhesion and higher hardness than a urethane material. Therefore, vibration of the vibration device 500 may be easily transferred to the vibration member 100.

For example, a reflective sheet for reflecting sound is essential for a radial speaker designed to enable listening in various directions. For example, the reflective sheet is disposed to be spaced apart from the speaker at the top of the speaker to reflect the sound transmitted from the speaker. For example, the reflective sheet may be a radiation lens or the like for reflecting the sound transmitted from the speaker. Therefore, the radial speaker may increase the manufacturing cost of the apparatus and increase the thickness of the apparatus.

According to the embodiment of the present disclosure, since the vibration member 100 includes the round portion 130 and the internal space and the vibration device 500 is configured in the internal space, sound having improved sound characteristics and/or improved sound pressure characteristics may be output in all directions without adding a separate sound reflective sheet. Therefore, the apparatus 1 according to the embodiment of the present disclosure may implement process optimization by reducing production energy, and may implement a lightweight apparatus 1 through weight reduction.

According to the embodiment of the present disclosure, since the vibration member 100 includes the plane portion 110 having a uniform thickness, the vibration device 500 may be more stably connected to the vibration member 100.

According to the embodiment of the present disclosure, the apparatus 1 has a simple configuration, and may be easily coupled to various apparatuses by using the adhesive member.

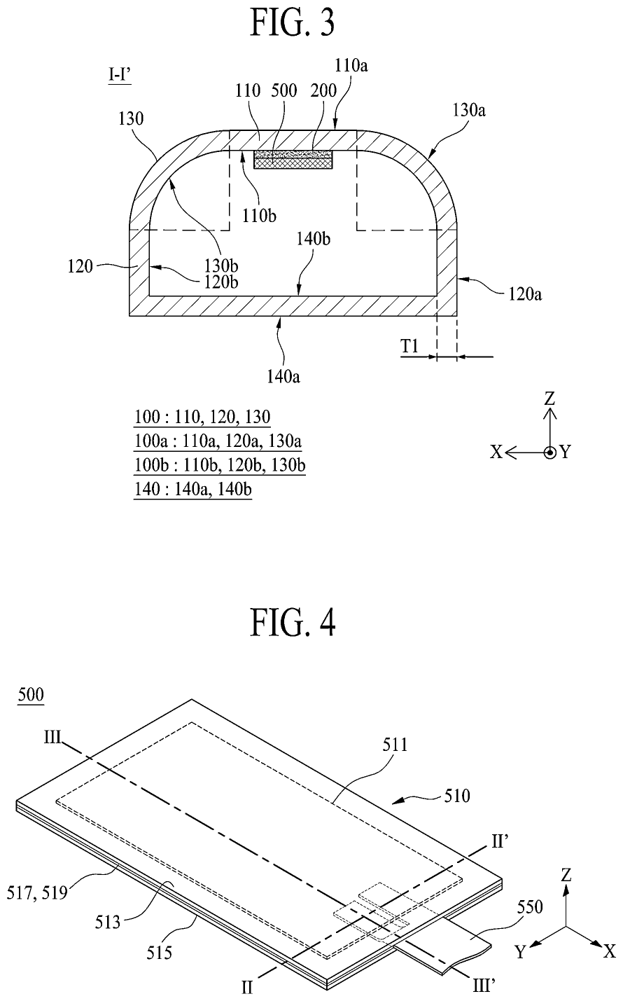

FIG. 3 is another cross-sectional view taken along line I-I′ shown in FIG. 1. Except for that the vibration member further includes a bottom portion, the apparatus according to another embodiment of the present disclosure may be the same as the an apparatus according to an embodiment of the present disclosure described above with reference to FIGS. 1 to 2. Hereinafter, therefore, different elements will be described.

Referring to FIG. 3, according to another embodiment of the present disclosure, the vibration member 100 may include a plane portion 110, a side portion 120, a round portion 130 and a bottom portion 140. The vibration member 100 may be configured in the same manner as the embodiment of the present disclosure described with reference to FIGS. 1 and 2.

According to the embodiment of the present disclosure, the bottom portion (or a third extension portion) 140 may be disposed to face the plane portion 110 and extended to be perpendicular from the side portion 120. The bottom portion 140 may be disposed to be parallel with the plane portion 110. The bottom portion 140 may be connected to the side portion 120 to seal the internal space G. The bottom portion 140 may include a flat panel structure having a uniform thickness as a whole. For example, the bottom portion 140 may include a circular flat panel structure. According to the embodiment of the present disclosure, the bottom portion 140 may include a first surface 140a and a second surface 140b. In the bottom portion 140, the first surface 140a may be an outer side. The second surface 140b may be an inner side. According to the embodiment of the present disclosure, the bottom portion 140 may have the same thickness as that each of the plane portion 110, the side portion 120 and the round portion 130, but the embodiments of the present disclosure are not limited thereto. For example, the thickness of the plane portion 110 may be in the range of 1 mm to 3 mm.

According to another embodiment of the present disclosure, the adhesive member may be attached to the bottom portion 140 so that the bottom portion 140 may be more easily coupled to various apparatuses.

According to another embodiment of the present disclosure, since the vibration member 100 includes the round portion 130 and the internal space and the vibration device 500 is configured in the internal space, sound having improved sound characteristics and/or improved sound pressure characteristics may be output in all directions without adding a separate sound reflective sheet. Therefore, the apparatus 1 according to the embodiment of the present disclosure may implement process optimization by reducing production energy, and may implement a lightweight apparatus 1 through weight reduction.

According to another embodiment of the present disclosure, since the vibration member 100 includes the plane portion 110 having a uniform thickness, the vibration device 500 may be more stably connected to the vibration member 100.

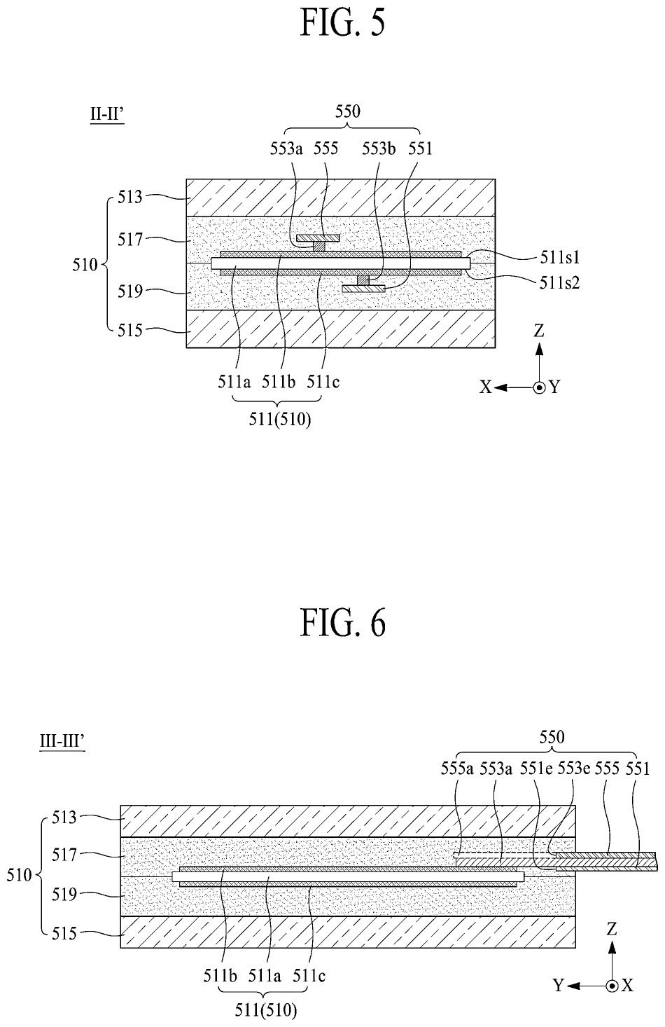

FIG. 4 is a view illustrating a vibration device according to the embodiment of the present disclosure. FIG. 5 is a cross-sectional view taken along line II-II′ shown in FIG. 4. FIG. 6 is a cross-sectional view taken along line III-III′ shown in FIG. 4. FIGS. 4 to 6 show the vibration apparatus described with reference to FIGS. 1 to 3.

Referring to FIGS. 4 to 6, the vibration device 500 according to the embodiment of the present disclosure may include one or more vibration generators.

The vibration device 500 or the one or more vibration generators may include a vibration generating unit 510 containing a piezoelectric material. The vibration generating unit 510 may be configured to be vibrated by a driving signal (or a sound signal or a voice signal). For example, the vibration generating unit 510 may be a vibration device, a vibration generating element, a vibration film, a vibration generating film, a vibrator, a vibration generator, an active vibrator, an active vibration generator or an active vibration member, but the embodiments of the present disclosure are not limited thereto.

The vibration generating unit 510 according to one embodiment of the present disclosure may include a vibration portion 511. The vibration portion 511 may be configured to be vibrated by a piezoelectric effect according to a driving signal. The vibration portion 511 may include at least one of a piezoelectric inorganic material and a piezoelectric organic material. For example, the vibration portion 511 may be a piezoelectric element, a piezoelectric element unit, a piezoelectric element layer, a piezoelectric structure, a piezoelectric vibration portion or a piezoelectric vibration layer, and the embodiments of the present disclosure are not limited thereto.

The vibration generating unit 510 or the vibration portion 511 according to the embodiment of the present disclosure may include a vibration layer 511a, a first electrode layer 511b and a second electrode layer 511c.

The vibration layer 511a may include a piezoelectric material or an electroactive material, which includes a piezoelectric effect. For example, the piezoelectric material may have characteristics in which a potential difference is generated by a dielectric polarization according to a relative position change of positive (+) ions and negative (−) ions while a pressure or torsion phenomenon is applied to a crystal structure by an external force, whereas vibration is generated by an electric field according to an applied voltage. For example, the vibration layer 511a may be a piezoelectric layer, a piezoelectric material layer, an electroactive layer, a piezoelectric composite layer, a piezoelectric composite or a piezoelectric ceramic composite, and the embodiments of the present disclosure are not limited thereto. The vibration layer 511a may include a plurality of inorganic material portions having piezoelectric characteristics and an organic material portion between the plurality of inorganic material portions.

The vibration layer 511a may be made of a ceramic-based material capable of implementing relatively strong vibration or a piezoelectric ceramic having a perovskite-based crystal structure. The perovskite-based crystal structure may have a piezoelectric and/or reverse piezoelectric effect, and may be a plate-shaped structure having orientation.

The piezoelectric ceramic may include single-crystal ceramic having a single-crystal structure, or may include a ceramic material or poly-crystal ceramic having a poly-crystal structure. A piezoelectric material including single-crystal ceramic may include aluminum phosphate (for example, berlinite and α-AlPO₄), silicon dioxide (for example, α-SiO₂), lithium niobate (LiNbO₃), terbium molydbate (Tb₂(MoO₄)₃), lithium tetraborate (Li₂B₄O₇), or ZnO, but embodiments of the present disclosure are not limited thereto. The piezoelectric material including polycrytalline ceramic may include a lead zirconate titanate (PZT)-based material including lead (Pb), zirconium (Zr), and titanium (Ti) or may include a lead zirconate nickel niobate (PZNN)-based material including lead (Pb), zirconium (Zr), nickel (Ni), and niobium (Nb), but embodiments of the present disclosure are not limited thereto. As another example, the vibration layer 511a may include at least one of CaTiO₃, BaTiO₃, and SrTiO₃ including no Pb, but embodiments of the present disclosure are not limited thereto.

The first electrode layer 511b may be disposed on a first surface (or an upper surface or a front surface) 511s1 of the vibration layer 511a. The first electrode layer 511b may have the same size as that of the vibration layer 511a, or may have a size smaller than that of the vibration layer 511a.

The second electrode layer 511c may be disposed on a second surface (or a lower surface or a rear surface) 511s2 different from or opposite to the first surface 511s1 of the vibration layer 511a. The second electrode layer 511c may have the same size as that of the vibration layer 511a, or may have a size smaller than that of the vibration layer 511a. For example, the second electrode layer 511c may have the same shape as that of the vibration layer 511a, but the embodiments of the present disclosure are not limited thereto.

According to an embodiment of the present disclosure, each of the first electrode layer 511b and the second electrode layer 511c may be formed at the other portion, except an edge portion, of the vibration layer 511a so as to prevent an electrical connection (or short circuit) between the first electrode layer 511b and the second electrode layer 511c. For example, the first electrode layer 511b may be formed on the whole first surface, except the edge portion, of the vibration layer 511a. For example, the second electrode layer 511c may be formed on the whole second surface, except the edge portion, of the vibration layer 511a. For example, a distance between a lateral surface (or an outer sidewall) of the vibration layer 511a and a lateral surface (or an outer sidewall) of each of the first electrode layer 511b and the second electrode layer 511c may be at least 0.5 mm or more, but embodiments of the present disclosure are not limited thereto. For example, the distance between the lateral surface of the vibration layer 511a and the lateral surface of each of the first electrode layer 511b and the second electrode layer 511c may be at least 1 mm or more, but embodiments of the present disclosure are not limited thereto.

According to an embodiment of the present disclosure, one or more of the first electrode layer 511b and the second electrode layer 511c may include a transparent conductive material, a semitransparent conductive material, or an opaque conductive material. For example, the transparent or semitransparent conductive material of one or more of the first electrode layer 511b and the second electrode layer 511c may include indium tin oxide (ITO) or indium zinc oxide (IZO), but embodiments of the present disclosure are not limited thereto. The opaque conductive material may include gold (Au), silver (Ag), platinum (Pt), palladium (Pd), molybdenum (Mo), magnesium (Mg), carbon, or glass frit-containing silver (Ag), or an alloy thereof, but embodiments of the present disclosure are not limited thereto. For example, each of the first electrode layer 511b and the second electrode layer 511c may include silver (Ag) having a low resistivity, so as to enhance an electrical characteristic and/or a vibration characteristic of the vibration layer 511a. For example, carbon may be a carbon material including carbon black, ketjen black, carbon nanotube, and graphite, but embodiments of the present disclosure are not limited thereto.

In the first electrode layer 511b and the second electrode layer 511c including glass frit-containing silver (Ag), a content of glass frit may be about 1 wt % to about 12 wt %, but embodiments of the present disclosure are not limited thereto. The glass frit may include a material based on PbO or Bi₂O₃, but embodiments of the present disclosure are not limited thereto.

The vibration layer 511a may be polarized (or poled) by a constant voltage applied to the first electrode layer 511b and the second electrode layer 511c under a constant temperature atmosphere or a temperature atmosphere which changes from a high temperature to room temperature, but the embodiments of the present disclosure are not limited thereto. For example, a polarization direction (or a poling direction) formed in the vibration layer 511a may be formed or aligned (or arranged) from the first electrode layer 511b to the second electrode layer 511c but is not limited thereto, and may be formed or aligned (or arranged) from the second electrode layer 511c to the first electrode layer 511b.

The vibration layer 511a may be vibrated as contraction and/or expansion is alternately repeated by a reverse piezoelectric effect according to a sound signal (or voice signal) applied from the outside to the first electrode layer 511b and the second electrode layer 511c. For example, the vibration layer 511a may be vibrated in the vertical direction (or thickness direction) and a plane direction by the signal applied to the first electrode layer 511b and the second electrode layer 511c. The vibration layer 511a may be displaced (or vibrated or driven) by contraction and/or expansion in a plane direction, thereby improving vibration characteristics including sound characteristics and/or sound pressure characteristics of the vibration generating unit 510 or the vibration device 500.

The vibration device 500 or the vibration generating unit 510 according to one embodiment of the present disclosure may further include a first cover member 513 and a second cover member 515.

The first cover member 513 may be disposed on a first surface of the vibration portion 511. For example, the first cover member 513 may be configured to cover the first electrode layer 511b of the vibration portion 511. For example, the first cover member 513 may be configured to have a size greater than that of the vibration portion 511. The first cover member 513 may be configured to protect the first surface and the first electrode layer 511b of the vibration portion 511.

The second cover member 515 may be disposed on a second surface of the vibration portion 511. For example, the second cover member 515 may be configured to cover the second electrode layer 511c of the vibration portion 511. For example, the second cover member 515 may be configured to have a size greater than that of the vibration portion 511, and may be configured to have the same size as that of the first cover member 513. The second cover member 515 may be configured to protect the second surface and the second electrode layer 511c of the vibration portion 511.

Each of the first cover member 513 and the second cover member 515 according to an embodiment of the present disclosure may include one or more materials of plastic, fiber, cloth, paper, leather, rubber, and wood, but embodiments of the present disclosure are not limited thereto. For example, the first cover member 513 and the second cover member 515 may include the same material or different materials. For example, each of the first cover member 513 and the second cover member 515 may be a polyimide film or a polyethylene terephthalate film, but embodiments of the present disclosure are not limited thereto.

One or more of the first cover member 513 and the second cover member 515 according to one embodiment of the present disclosure may include an adhesive member. For example, one or more of the first cover member 513 and the second cover member 515 may include an adhesive member coupled to or bonded to the vibration portion 511, and a protective member (or a laminating member) covering or protecting the adhesive member. For example, the adhesive member may include an electrically insulating material capable of being compressed and restored while having adhesion. For example, the first cover member 513 may include an adhesive member coupled to or bonded to the vibration portion 511, and a protective member (or a laminating member) covering or protecting the adhesive member.

The first cover member 513 may be connected or coupled to the first surface or the first electrode layer 511b of the vibration portion 511 via the first adhesive layer 517. For example, the first cover member 513 may be connected or coupled to the first surface or the first electrode layer 511b of the vibration portions 511 by a film laminating process that uses the first adhesive layer 517 as a medium.

The second cover member 515 may be connected or coupled to the second surface or the second electrode layer 511c of the vibration portion 511 via a second adhesive layer 519. For example, the second cover member 515 may be connected or coupled to the second surface or the second electrode layer 511c of the vibration portion 511 by a film laminating process that uses the second adhesive layer 519 as a medium.

Each of the first adhesive layer 517 and the second adhesive layer 519 according to one embodiment of the present disclosure may include an electrically insulating material capable of being compressed and restored while having adhesion. For example, each of the first adhesive layer 517 and the second adhesive layer 519 may include an epoxy resin, an acrylic resin, a silicon resin or a urethane resin, but the embodiments of the present disclosure are not limited thereto.

The first adhesive layer 517 and the second adhesive layer 519 may be configured between the first cover member 513 and the second cover member 515 to surround the vibration portion 511. For example, one or more of the first adhesive layer 517 and the second adhesive layer 519 may be configured to surround the vibration portion 511.

The vibration device 500 (or one or more vibration generators) according to one embodiment of the present disclosure may further include a signal supply member 550.

The signal supply member 550 may be configured to supply a driving signal supplied from a vibration driving circuit to the vibration generating unit 510. The signal supply member 550 may be configured to be electrically connected to the vibration portion 511 at one side of the vibration generating unit 510. The signal supply member 550 may be configured to be electrically connected to the first electrode layer 511b and the second electrode layer 511c of the vibration portion 511.

A portion of the signal supply member 550 may be accommodated between the first cover member 513 and the second cover member 515. An end portion of the signal supply member 550 may be disposed or inserted (or accommodated) in a portion between one edge portion of the first cover member 513 and one edge portion of the second cover member 515. One edge portion of the first cover member 513 and one edge portion of the second cover member 515 may accommodate or vertically cover the end portion of the signal supply member 550. Therefore, the signal supply member 550 may be integrated with the vibration generating unit 510. For example, the vibration device 500 according to one embodiment of the present disclosure may be a vibration apparatus with which the signal supply member 550 is integrated. For example, the signal supply member 550 may include a signal cable, a flexible cable, a flexible printed circuit cable, a flexible flat cable, a cross-section flexible printed circuit, a cross-section flexible printed circuit board, a flexible multilayer printed circuit or a flexible multilayer printed circuit board, but the embodiments of the present disclosure are not limited thereto.

The signal supply member 550 according to one embodiment of the present disclosure may include a base member 551 and a plurality of signal lines 553a and 553b. For example, the signal supply member 550 may include a base member 551, a first signal line 553a and a second signal line 553b.

The base member 551 may include a transparent or opaque plastic material. For example, the base member 551 may include one or more of resins such as fluorine resin, polyimide-based resin, polyurethane-based resin, polyester-based resin, polyethylene-based resin, and polypropylene-based resin, but embodiments of the present disclosure are not limited thereto. The base member 551 may be a base film or a base insulation film, but embodiments of the present disclosure are not limited thereto.

The base member 551 may have a predetermined width along the first direction X, and may be extended to be long along the second direction Y crossing the first direction X.

The first and second signal lines 553a and 553b may be disposed on a first surface of the base member 551 so as to be parallel with the second direction Y, and may be spaced apart from each other along the first direction X or electrically separated from each other. The first and second signal lines 553a and 553b may be disposed to be parallel with each other on the first surface of the base member 551. For example, the first and second signal lines 553a and 553b may be implemented in a line shape by patterning of a metal layer (or conductive layer) formed or deposited on the first surface of the base member 551.

End portions of the first and second signal lines 553a and 553b may be individually curved or bent by being separated from each other.

The end portion of the first signal line 553a may be electrically connected to the first electrode layer 511b of the vibration portion 511. For example, the end portion of the first signal line 553a may be electrically connected to at least a portion of the first electrode layer 511b of the vibration portion 511 at one edge portion of the first cover member 513. For example, the end portion of the first signal line 553a may be electrically and directly connected to at least a portion of the first electrode layer 511b of the vibration portion 511. For example, the end portion of the first signal line 553a may be directly connected to or directly in contact with the first electrode layer 511b of the vibration portion 511. For example, the end portion of the first signal line 553a may be electrically connected to the first electrode layer 511b through a conductive double-sided tape. Therefore, the first signal line 553a may supply a first driving signal supplied from the vibration driving circuit to the first electrode layer 511b of the vibration portion 511.

The end portion of the second signal line 553b may be electrically connected to the second electrode layer 511c of the vibration portion 511. For example, the end portion of the second signal line 553b may be electrically connected to at least a portion of the second electrode layer 511c of the vibration portion 511 at one edge portion of the second cover member 515. For example, the end portion of the second signal line 553b may be electrically and directly connected to at least a portion of the second electrode layer 511c of the vibration portion 511. For example, the end portion of the second signal line 553b may be directly connected to or directly in contact with the second electrode layer 511c of the vibration portion 511. For example, the end portion of the second signal line 553b may be electrically connected to the second electrode layer 511c through a conductive double-sided tape. Therefore, the second signal line 553b may supply a second driving signal supplied from the vibration driving circuit to the second electrode layer 511c of the vibration portion 511.

The signal supply member 550 according to one embodiment of the present disclosure may further include an insulating layer 555.

The insulating layer 555 may be disposed on the first surface of the base member 551 to cover each of the remaining first signal line 553a and the second signal line 553b except the end portion (or one side) of the signal supply member 550.

The end portion (or one side) of the signal supply member 550 including the end portion (or one side) of the base member 551 may be inserted (or accommodated) between the first surface of the vibration portion 511 and the first cover member 513, and may be inserted (or accommodated) and fixed between the first surface of the vibration portion 511 and the first cover member 513 by the first adhesive layer 517. For example, the end portion (or one side) of the signal supply member 550 inserted (or accommodated) between the first surface of the vibration portion 511 and the first cover member 513 may be inserted (or accommodated) and fixed between the first surface of the vibration portion 511 and the first cover member 513 by a film laminating process that uses the first adhesive layer 517 and/or the second adhesive layer 519 as a medium. Therefore, the end portion (or one side) of the first signal line 553a may be maintained in a state that it is electrically connected to the first electrode layer 511b of the vibration portion 511, and the end portion (or one side) of the second signal line 553b may be maintained in a state that it is electrically connected to the second electrode layer 511c of the vibration portion 511. In addition, the end portion (or one side) of the signal supply member 550 is inserted (or accommodated) and fixed between the vibration portion 511 and the first cover member 513, whereby a connection failure between the vibration generating unit 510 and the signal supply member 550 due to movement of the signal supply member 550 may be avoided.

In the signal supply member 550 according to the embodiment of the present disclosure, each of the end portion (or one side) of the base member 551 and the end portion (or one side) 555a of the insulating layer 555 may be removed. For example, each of the end portion of the first signal line 553a and the end portion of the second signal line 553b may be exposed to the outside without being supported or covered by each of the end portion (or one side) of the base member 551 and the end portion (or one side) 555a of the insulating layer 555. For example, the end portion of each of the first and second signal lines 553a and 553b may be protruded (or extended) to have a predetermined length from an end 551e of the base member 551 or an end 553e of the insulating layer 555. Therefore, each end portion of each of the first and second signal lines 553a and 553b may be individually or independently bent.

Each of the first and second signal lines 553a and 553b may be disposed only between the base member 551 and the insulating layer 555. The end portion (or one side) of the first signal line 553a, which is not supported by each of the end portion (or one side) of the base member 551 and the end portion (or one side) 555a of the insulating layer 555, may be directly connected to or directly in contact with the first electrode layer 511b of the vibration portion 511. The end portion (or one side) of the second signal line 553b, which is not supported by each of the end portion (or one side) of the base member 551 and the end portion (or one side) 555a of the insulating layer 555, may be directly connected to or directly in contact with the second electrode layer 511c of the vibration portion 511.

According to one embodiment of the present disclosure, a portion of the signal supply member 550 is disposed or inserted (or accommodated) between the vibration portion 511 and the first cover member 513 so that the signal supply member 550 may be integrated with the vibration generating unit 510. Therefore, the signal supply member 550 and the vibration generating unit 510 may be configured as one component, whereby an effect of uni material may be obtained.

According to one embodiment of the present disclosure, as the first signal line 553a and the second signal line 553b of the signal supply member 550 are integrated with the vibration generating unit 510, a soldering process for electrical connection between the vibration generating unit 510 and the signal supply member 550 is not required and thus a structure and a manufacturing process of the vibration device 500 may be simplified, whereby a harmful process may be resolved.

Additionally, the vibration device 500 according to the embodiment of the present disclosure may include a plurality of vibration generating units. In this case, the plurality of vibration generating units may have a stacked structure, and may be vibrated in the same direction. Therefore, the embodiment of the present disclosure may further improve sound characteristics.

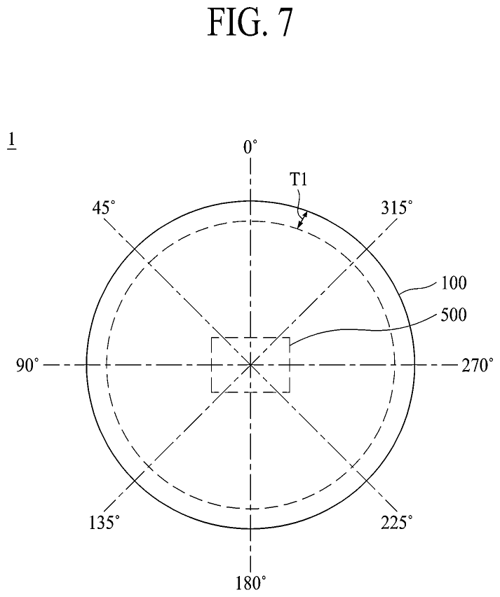

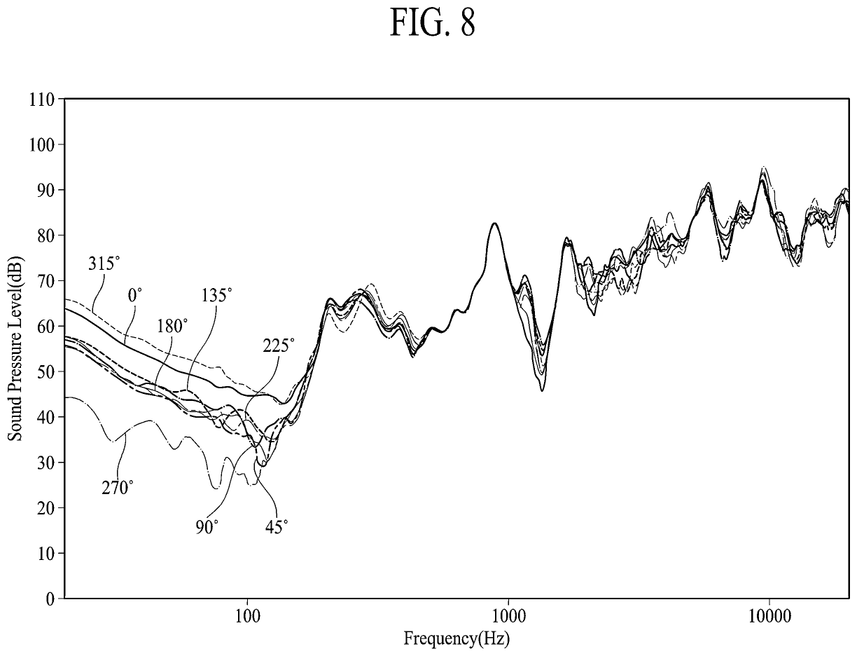

FIG. 7 is a plan view illustrating a frequency measurement range of an apparatus according to the embodiment of the present disclosure. FIG. 8 is a view illustrating sound output characteristics per frequency of an apparatus according to the embodiment of the present disclosure. In FIG. 8, the horizontal axis represents frequency (Hz), and the vertical axis represents sound pressure level (dB).

As shown in FIG. 7, the inventors of the present disclosure measured sound characteristics according to frequencies for respective positions of 0°, 45°, 90°, 135°, 180°, 225°, 270° and 315° of the apparatus according to the present disclosure. For example, after a microphone is positioned at a point of Im away from each position, sound characteristics according to frequency were evaluated.

As shown in FIG. 8, according to the embodiment of the present disclosure, sound characteristics according to frequencies for respective positions of 0°, 45°, 90°, 135°, 180°, 225°, 270° and 315° were different from one another at a frequency of 100 Hz or less. For example, in case of 100 Hz or less, a measurement value at 270° indicated a value of 45 dB or less, and a measurement value at 0° and 45° indicated a value of 65 dB or less. For example, in case of 100 Hz or less, the measurement values at 90°, 135°, 180°, 225° and 315° indicated similar values of 60 dB or less. For example, in case of 150 Hz or more, sound characteristics according to frequencies for respective positions of 0°, 45°, 90°, 135°, 180°, 225°, 270° and 315° were equally measured.

Therefore, according to the embodiment of the present disclosure, it was noted that the apparatus had similar sound characteristics in all directions.

According to the embodiment of the present disclosure, since the vibration member 100 includes the round portion 130 and the internal space G and the vibration device 500 is configured in the internal space, sound having improved sound characteristics and/or improved sound pressure characteristics may be output in all directions without adding a separate sound reflective sheet. Therefore, the apparatus 1 according to the embodiment of the present disclosure may implement process optimization by reducing production energy, and may implement a lightweight apparatus 1 through weight reduction.

The apparatus according to the embodiment of the present disclosure may be applied to the vibration generating apparatus and/or the sound generating apparatus. The apparatus according to the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic diary, an electronic book, a portable multimedia player (PMP), a personal digital assistant (PDA), an MP3 player, a mobile medical apparatus, a desktop PC, a laptop PC, a netbook computer, a workstation, a navigator, a vehicle navigator, a vehicle display apparatus, a vehicle apparatus, a theater display apparatus, a television, a wall paper apparatus, a signage apparatus, a game apparatus, a laptop computer, a monitor, a camera, a camcorder, home appliances, etc.

The apparatus according to the embodiment of the present disclosure may be described as follows.

According to some embodiments of the present disclosure, an apparatus comprises a vibration member including a plane portion and a round portion extended to be rounded from the plane portion, and a vibration device connected to the vibration member.

According to some embodiments of the present disclosure, the vibration device is disposed on an inner side of the plane portion.

According to some embodiments of the present disclosure, the vibration member includes a side portion extended from the round portion and configured to be perpendicular to the plane portion.

According to some embodiments of the present disclosure, the vibration member has a uniform thickness.

According to some embodiments of the present disclosure, the thickness of the vibration member is 1 mm to 3 mm.

According to some embodiments of the present disclosure, the round portion connects the plane portion with the side portion.

According to some embodiments of the present disclosure, the vibration member has an internal space.

According to some embodiments of the present disclosure, the vibration device is disposed in the internal space.

According to some embodiments of the present disclosure, the internal space is configured by an inner side of each of the plane portion, the round portion and the side portion.

According to some embodiments of the present disclosure, the vibration member further includes a bottom portion facing the plane portion, and extended to be perpendicular from the side portion.

According to some embodiments of the present disclosure, the internal space is sealed by the bottom portion.

According to some embodiments of the present disclosure, the vibration member includes a porous plastic material or an ultra-fine foam plastic material.

According to some embodiments of the present disclosure, the apparatus further comprises a connection member between the vibration device and the vibration member.

According to some embodiments of the present disclosure, the vibration device includes a vibration layer, a first electrode layer on a first surface of the vibration layer, and a second electrode layer on a second surface of the vibration layer, which is different from the first surface.

According to some embodiments of the present disclosure, the vibration layer includes a plurality of inorganic material portions having piezoelectric characteristics, and an organic material portion between the plurality of inorganic material portions.

According to some embodiments of the present disclosure, the vibration device includes a plurality of vibration portions spaced apart from each other, each of the plurality of vibration portions includes a vibration layer, a first electrode layer on a first surface of the vibration layer, and a second electrode layer on a second surface of the vibration layer, which is different from the first surface.

According to some embodiments of the present disclosure, the vibration device includes a first cover member commonly connected to the first electrode layers of the plurality of vibration portions, and a second cover member commonly connected to the second electrode layers of the plurality of vibration portions.

According to some embodiments of the present disclosure, the vibration layer of each of the plurality of vibration portions includes a plurality of inorganic material portions having piezoelectric characteristics, and an organic material portion between the plurality of inorganic material portions.

According to some embodiments of the present disclosure, the vibration device includes a plurality of vibration generating units, and the plurality of vibration generating units are vibrated in the same direction.

It will be apparent to those skilled in the art that various modifications and variations can be made in the apparatus of the present disclosure without departing from the technical idea or scope of the disclosure. Thus, it is intended that the present disclosure cover the modifications and variations of this disclosure provided they come within the scope of the appended claims and their equivalents.

What is claimed is:

1. An apparatus, comprising:
a vibration member including a plane portion and a round portion extended to be rounded from the plane portion; and
a vibration device connected to the vibration member.

2. The apparatus of claim 1, wherein the vibration device is disposed on an inner side of the plane portion.

3. The apparatus of claim 1, wherein the vibration member includes a side portion extended from the round portion and configured to be perpendicular to the plane portion.

4. The apparatus of claim 1, wherein the vibration member has a uniform thickness.

5. The apparatus of claim 4, wherein the thickness of the vibration member is 1 mm to 3 mm.

6. The apparatus of claim 3, wherein the round portion connects the plane portion with the side portion.

7. The apparatus of claim 6, wherein the vibration member has an internal space.

8. The apparatus of claim 7, wherein the vibration device is disposed in the internal space.

9. The apparatus of claim 7, wherein the internal space is configured by an inner side of each of the plane portion, the round portion and the side portion.

10. The apparatus of claim 7, wherein the vibration member further includes a bottom portion facing the plane portion, and extended to be perpendicular from the side portion.

11. The apparatus of claim 10, wherein the internal space is sealed by the bottom portion.

12. The apparatus of claim 1, wherein the vibration member includes a porous plastic material or an ultra-fine foam plastic material.

13. The apparatus of claim 1, further comprising a connection member between the vibration device and the vibration member.

14. The apparatus of claim 1, wherein the vibration device includes:
a vibration layer;
a first electrode layer on a first surface of the vibration layer; and
a second electrode layer on a second surface of the vibration layer, which is different from the first surface.

15. The apparatus of claim 14, wherein the vibration layer includes:
a plurality of inorganic material portions having piezoelectric characteristics; and
an organic material portion between the plurality of inorganic material portions.

16. The apparatus of claim 1, wherein the vibration device includes a plurality of vibration portions spaced apart from each other,
each of the plurality of vibration portions includes:
a vibration layer;
a first electrode layer on a first surface of the vibration layer; and
a second electrode layer on a second surface of the vibration layer, which is different from the first surface.

17. The apparatus of claim 16, wherein the vibration device includes:
a first cover member commonly connected to the first electrode layers of the plurality of vibration portions; and
a second cover member commonly connected to the second electrode layers of the plurality of vibration portions.

18. The apparatus of claim 16, wherein the vibration layer of each of the plurality of vibration portions includes:
a plurality of inorganic material portions having piezoelectric characteristics; and
an organic material portion between the plurality of inorganic material portions.

19. The apparatus of claim 1, wherein the vibration device includes a plurality of vibration generating units, and
the plurality of vibration generating units are vibrated in the same direction.

20. The apparatus of claim 2, wherein a circumference of the side portion is greater than that of the plane portion.

21. The apparatus of claim 1, wherein the plane portion includes a flat panel structure having a uniform thickness as a whole.

22. The apparatus of claim 1, wherein the round portion includes a non-planar structure having a uniform thickness as a whole.

23. The apparatus of claim 1, wherein a curvature radius of the round portion is 25 mm to 100 mm.

24. The apparatus of claim 14, wherein each of the first electrode layer and the second electrode layer has a size equal to or smaller than that of the vibration layer, or
wherein each of the first electrode layer and the second electrode layer is formed at the other portion, except an edge portion, of the vibration layer.

25. The apparatus of claim 16, wherein each of the first electrode layer and the second electrode layer has a size equal to or smaller than that of the vibration layer, or
wherein each of the first electrode layer and the second electrode layer is formed at the other portion, except an edge portion, of the vibration layer.

26. The sound apparatus of claim 17, wherein the vibration device further includes a signal supply member electrically connected to the first electrode layer and the second electrode layer, and
an end portion of the signal supply member is accommodated in a portion between one edge portion of the first cover member and one edge portion of the second cover member.
